(19) United States
(12) Patent Application Publication
(10) Pub. No.: US 2025/0233058 A1
(43) Pub. Date: Jul. 17, 2025

(54) SEMICONDUCTOR PACKAGE STRUCTURE AND METHOD OF FABRICATING THE SAME

(71) Applicant: Richtek Technology Corporation, Zhubei City (TW)

(72) Inventors: Shih-Chieh Lin, Kaohsiung (TW); Min-Shun Lo, Miaoli (TW); Sheng-Yao Wu, Hsinchu (TW); Heng-Chi Huang, Hsinchu (TW); Yong-Zhong Hu, Hsinchu (TW)

(21) Appl. No.: 18/588,977

(22) Filed: Feb. 27, 2024

(30) Foreign Application Priority Data
Jan. 11, 2024 (TW) 113101266

(51) Int. Cl. H01L 23/498; H01L 21/48

(52) U.S. Cl. CPC H01L 23/49816; H01L 21/4853; H01L 23/49838

(57) ABSTRACT

A semiconductor package structure includes: an interposer board, including a top side and a bottom side; a first ball grid array located on the bottom side of the interposer board, the first ball grid array including plural first soldering balls, wherein the first ball grid array provides a signal connection function between the interposer board and an external printed circuit board; and a second ball grid array located on the bottom side of the interposer board, the second ball grid array including plural second soldering balls, which are positioned within gaps between the first soldering balls on the bottom side.

### CROSS REFERENCE

The present invention claims priority to TW 113101266 filed on Jan. 11, 2024.

### BACKGROUND OF THE INVENTION

### Field of Invention

The present invention relates to a semiconductor packaging technology that can be applied to a ball grid array in chip packaging, especially a packaging technology that can achieve a longer lifespan of soldering balls in ball grid arrays.

### Description of Related Art

In semiconductor packaging, the ball grid array (BGA) may develop cracks during thermal cycling tests or the BGA ball planting process, leading to quality shortcomings, such as shortened product lifespan of the chip. Additionally, in conventional wafer-level packaging technologies, the redistribution layer (RDL) requires layout design for numerous signal connection routes. Many of these routed paths may suffer from signal delays due to excessive length or other parasitic effects, impacting the overall operation speed.

The packaging technique proposed in the present invention can significantly mitigate the issue of ball cracks and reduce the complexity of routing in the redistribution layer (RDL), thereby enhancing the semiconductor packaging quality.

### SUMMARY OF THE INVENTION

In one perspective, a semiconductor package structure provided by the present application includes: an interposer board, including a top side and a bottom side; a first ball grid array located on the bottom side of the interposer board, the first ball grid array including a plurality of first soldering balls, wherein the first ball grid array provides a signal connection function between the interposer board and an external printed circuit board; and a second ball grid array located on the bottom side of the interposer board, the second ball grid array including a plurality of second soldering balls, which are positioned within gaps between the first soldering balls on the bottom side.

In one embodiment, the semiconductor package structure further includes an integrated circuit, mounted on or above the top side.

In one embodiment, the first soldering balls are made of a conductive material, and the second soldering balls are made of a conductive material or a non-conductive material.

In one embodiment, in a reflow step, at least a portion of the first soldering balls are melted to be adhered to at least a portion of the second soldering balls; or, at least a portion of the second soldering balls are melted to be adhered to at least a portion of the first soldering balls.

In one embodiment, the second soldering balls are made of a conductive material, and the adhered second soldering balls and the first soldering balls form a redistribution circuit on the bottom side, wherein in the redistribution circuit, at least two of the first soldering balls are conducted to each other through the second soldering ball.

In one embodiment, the second soldering balls increase the solidified adhesion range on the bottom side after the first soldering balls are melted.

In one embodiment, in a reflow step, a portion of the second soldering balls are melted in the gaps between the first soldering balls, to form an adhesion structure, wherein the adhesion structure reduces an outward-exceeding height of the first soldering balls over the adhesion structure on the bottom side.

In one embodiment, the first and second soldering balls are respectively formed by two separate ball grid array forming processes.

In one embodiment, the first soldering balls and the second soldering balls are arranged on the bottom side in a non-stacked configuration.

In one embodiment, the first ball grid array and the second ball grid array are at the same layer level.

In one embodiment, there is at least one second soldering ball in the gap among four of the first soldering balls. In another embodiment, there is at least one second soldering ball in the gap between two of the first soldering balls.

In one embodiment, at least one of the first soldering balls includes a first lateral jut at a first lateral side of the first soldering ball facing the second soldering ball; or, at least one of the second soldering balls includes a second lateral jut at a second lateral side of the second soldering ball facing the first soldering ball; wherein, in a reflow step, the first and second lateral juts form a melted adhesion between the first and second soldering balls.

In another perspective, the invention provides a method of fabricating semiconductor package structure, which includes: providing an interposer board, which includes a top side and a bottom side, wherein an integrated circuit is disposed on or above the top side of the interposer board; performing a first ball grid array forming process to form a first ball grid array on the bottom side of the interposer board, the first ball grid array including a plurality of first soldering balls; performing a second ball grid array forming process to form a second ball grid array on the bottom side of the interposer board, the second ball grid array including a plurality of second soldering balls respectively disposed in gaps between the first soldering balls on the bottom sides; performing a reflow step, wherein during the reflow step, at least a portion of the first soldering balls are melted to be adhered to at least a portion of the second soldering balls; or, at least a portion of the second soldering balls are melted to be adhered to at least a portion of the first soldering balls; or, at least a portion of the first soldering balls and at least a portion of the second soldering balls are melted to be adhered to one another.

The objectives, technical details, features, and effects of the present invention will be better understood with regard to the detailed description of the embodiments below, with reference to the attached drawings.

### BRIEF DESCRIPTION OF THE DRAWINGS

FIG. 1 shows a schematic drawing of the semiconductor package structure according to one embodiment of the present invention.

FIGS. 2A to 2D respectively show several layout examples of the first and second soldering balls according to several embodiments of the present invention.

FIGS. 3A to 3D show several a process of forming the first and second soldering balls according to an embodiment of the present invention.

FIGS. 4A to 4G respectively show several examples of the first and second lateral juts according to several embodiments of the present invention.

FIG. 5 explains an outward-exceeding height of the first soldering balls over the adhesion structure on the bottom side.

### DESCRIPTION OF THE PREFERRED EMBODIMENTS

The drawings as referred to throughout the description of the present invention are for illustration only, to show the interrelations between the steps, the components or the units, but not drawn according to actual scale of sizes.

Referring to FIG. 1, from one perspective, the present invention provides a semiconductor packaging structure 10, comprising: an interposer board 110 with a top side 110t and a bottom side 110b; a first ball grid array 120 formed on the bottom side 110b of the interposer board 110, the first ball grid array 120 including multiple first soldering balls 122; and a second ball grid array 130, also formed on the bottom side 110b of the interposer board 110, the second ball grid array 130 including multiple second soldering balls 132, wherein the second soldering balls 132 are formed in the gaps Gp between the first soldering balls 122. In the figure, below the bottom side 110b, larger soldering balls represent the first soldering balls 122, and the first ball grid array 120 includes multiple first soldering balls 122; whereas, smaller soldering balls represent the second soldering balls 132, and the second ball grid array 130 includes multiple second soldering balls 132. The first ball grid array 120 provides a signal connection function between the interposer board 110 and an external printed circuit board PCB, achieved by the electrical connection of the first soldering balls 122 between the interposer board 110 and the external printed circuit board PCB. The semiconductor packaging structure 10 of the present invention can be, for example, a wafer-level packaging structure, other types of packaging structures, or a circuit board with a similar ball structure. The first and second ball grid arrays 120 and 130 are formed by different ball grid array forming processes, wherein the materials used for forming the first and second ball grid arrays 120 and 130 can be the same or different as the application requires, and the first and second soldering balls 122 and 132 can be the same size or different sizes as the application requires; detailed explanations will be made with reference to following embodiments. In the multiple ball grid arrays of the present invention, the first ball grid array 120 provides a signal connection function between the interposer board 110 and an external printed circuit board PCB, that is, the first soldering balls 122 of the first ball grid array 120 can serve as signal contacts for the external printed circuit board PCB, while the second soldering balls 132 of the second ball grid array 130 are not limited to functioning as signal contacts of the external printed circuit board PCB (the second soldering balls 132 do not need to be signal contacts). The above-mentioned design at least has the following merits: mitigating the soldering ball cracking issue commonly seen in the prior art, and reducing the negative effects caused by circuit routing or excessive length in the redistribution layer. The adhesion of the first and second soldering balls 122 and 132 increases the volume of the soldering balls, thus reducing the stress, and provides protection for the sides of the first soldering balls 122 in the first ball grid array 120, thus reducing the likelihood of lateral damage to the first soldering balls 122. In a case when the thermal conductivity of the material of the second soldering balls 132 is lower than that of the first soldering balls 122, the second soldering balls 132 can slow down the cool down speed of the first soldering balls 122 after a reflow step, to better maintain the stability of the solidified adhesion of the first soldering balls 122.

Please still refer to FIG. 1. In one embodiment, the semiconductor package structure 10 further includes an integrated circuit IC, mounted on or above the top side 110t. The integrated circuit IC and the interposer board 110 have a circuit connection between each other; signal and/or power transmissions can be achieved between the integrated circuit IC and the plural first soldering balls 122 on the bottom side of the interposer board 110, wherein the connection can be formed by, for example, wafer-level packaging or wire connection.

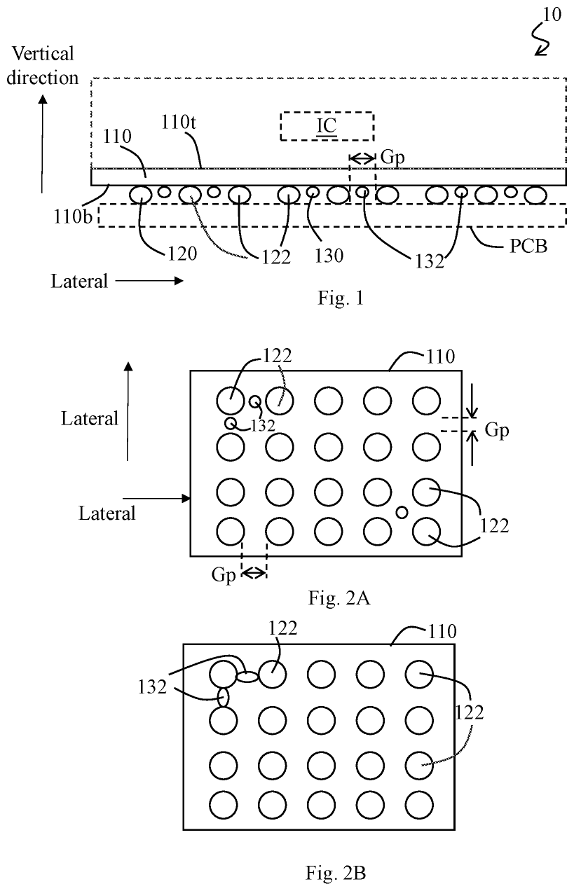

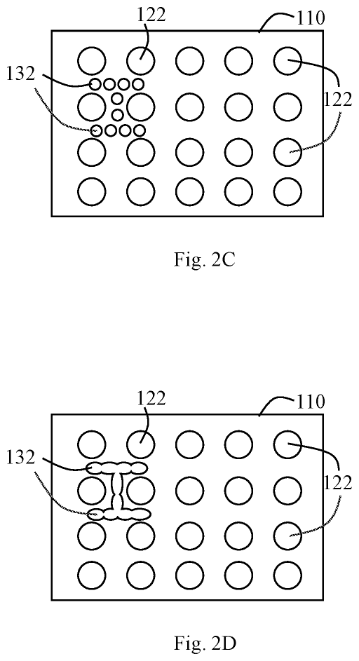

Please refer to FIGS. 1 and 2A, wherein the lateral direction corresponds to the planar direction (or horizontal direction) of the interposer board 110, and the vertical direction is the direction in which the interposer board 110 is connected to the outside printed circuit board PCB or integrated circuit IC. That is, the vertical direction is the direction from the interposer board 110 to the outside printed circuit board PCB or integrated circuit IC.

In one embodiment, the first soldering balls 122 include or are made of a conductive material, while the second soldering balls 132 include or are made of a conductive or a non-conductive material. The interposer board 110 and the first ball grid array 120 form a part of the electrical connection to transmit signals between the integrated circuit IC and the external printed circuit board PCB. FIG. 2A illustrates the state of the first and second soldering balls 122 and 132 on the bottom side 110b before the reflow step, wherein the quantities, sizes, and positions of the first and second soldering balls 122 and 132 are for illustrative purposes only. After the reflow step, the first and second soldering balls 122 and 132 may still remain unadhered to each other, similar to what is shown in FIG. 2A. Alternatively, as shown in FIG. 2B, adhesion between the first and second soldering balls 122 and 132 may form during the reflow step. When the second soldering balls 132 are made of a conductive material, their conductivity can provide an electrical connection between two first soldering balls 122. The embodiment shown in FIG. 2B illustrates the case wherein the second soldering balls 132 are melted and adhered to the first soldering balls 122, while in other cases, it may be the first soldering balls 122 that are melted and adhered to the second soldering balls 132, or both the first and second soldering balls 122 and 132 are melted and mutually adhered to each other. FIG. 2C shows an embodiment, wherein multiple second soldering balls 132 are arranged in a specific layoout between the first soldering balls 122. FIG. 2D shows the adhesion structure formed by melting the multiple second soldering balls 132 in FIG. 2C, wherein the adhesion structure is solely composed of the second soldering balls 132. In another embodiment, the melted second soldering balls 132 can also adhere to the surrounding first soldering balls 122.

The non-conductive material of the second soldering balls 132, for example, may include a conductive material at the center of the soldering ball, with its surface coated by a layer of non-conductive material; when the second soldering balls 132 partially are melted, they can still maintain their non-conductive characteristics. Alternatively, the second soldering balls 132 can be entirely made of a non-conductive material. The non-conduction is for the purpose that when the first and second soldering balls 122 and 132 are adhered to each other, they can maintain different electrical potentials, and there is no electrical conduction between the first and second soldering balls 122 and 132.

In one embodiment, during the reflow step, the melted portion of at least some of the first soldering balls 122 in the first ball grid array 120 adhere to at least some of the second soldering balls 132 in the second ball grid array 130. The reflow and adhesion may be achieved by effects such as surface tension. It is also possible that both the first and second soldering balls 122 and 132 are melted and adhered to each other. This depends on the layout design and the materials of the first and second soldering balls 122 and 132.

In one embodiment, the second soldering balls 132 are made of or include a conductive material. The mutually adhered second soldering balls 132 and first soldering balls 122 form a redistribution circuit beneath the bottom side 110b. This redistribution circuit is not the redistribution layer above the top side 110t but is rather an electrical connection formed between the first and second soldering balls 122 and 132 on the bottom side 110b. When the present invention is applied to CMOS integrated circuit applications, besides forming signal connections by the multiple layers within the CMOS integrated circuit, the present invention provides additional signal connection paths wherein signals can also be connected to designated first soldering balls 122 through the electrical conduction between the second soldering balls 132 and the first soldering balls 122.

In one embodiment, the existence of the second soldering balls 132 can increase the area of solidified adhesion of the first soldering balls 122 on the bottom side 110b of the interposer board 110 when the first soldering balls 122 are melted. For one of the reasons, the second soldering balls 132 increase the range of surface tension during the melting state of the first soldering balls 122, so that the first soldering balls 122 extend further outwards to the location of the lateral second soldering balls 132, and are adhered thereto solidification. Thus, after solidification, the area of solidified adhesion of the first soldering balls 122 is increased. Alternatively, the first and second soldering balls 122 and 132 may be melted and adhered to each other, jointly increasing the area of solidified adhesion on the bottom side 110b.

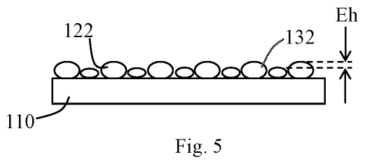

In one embodiment, in the reflow step, a portion of the second soldering balls 132 are melted into the gaps Gp between the first soldering balls 122, to form an adhesion structure. The adhesion structure reduces an outward-exceeding height Eh of the first soldering balls 122 over the adhesion structure on the bottom side 110b (FIG. 5). The second soldering balls 132 reduce the exposed side portion of the first soldering balls 122, providing protection for the sides of the first soldering balls 122. The second soldering balls 132 decrease the length by which the first soldering balls 122 protrude beyond the outer edge of the bottom side 110b, reducing the possibility of suffering damages to the sides of the first soldering balls 122 due to excessive protrusion length.

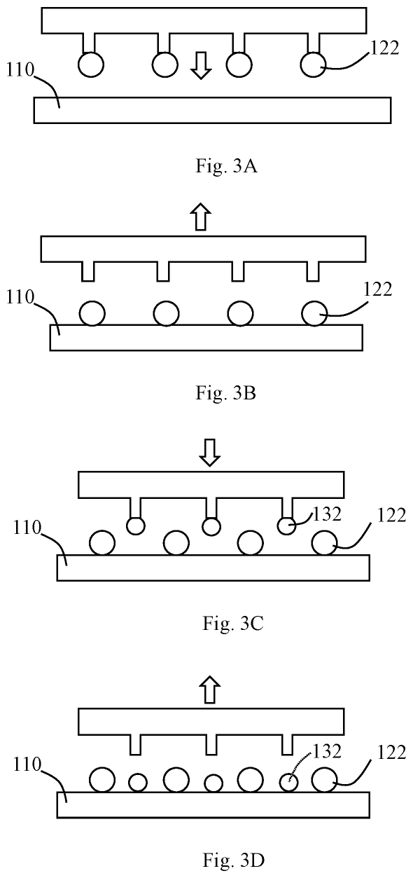

In one embodiment, the first soldering balls 122 and the second soldering balls 132 are respectively formed by two separate ball grid array forming processes (referring to FIGS. 3A to 3D). In this way, the second ball grid array 130 may, depending on the different requirements, place the second soldering ball 132 in different layouts, in the gap Gp between the first soldering balls 122. Thus, not limited by the same ball grid array forming process using the same material, the first and second soldering balls 122 and 132 can be formed differently with respect to materials and sizes.

In one embodiment, the first soldering balls 122 and the second soldering balls 132 are respectively formed on the bottom side 110b in a non-stacked configuration. In other words, the first soldering ball 122 and the second soldering ball 132 are located at the same layer level on the bottom side 110b.

There can be various ways to arrange the locations of the second soldering balls 132 between the first soldering balls 122 depending on requirements. In one embodiment, there is at least one second soldering ball 132 provided in the gap Gp between two of the first soldering balls. For example, in the upper left of FIG. 2A, one second soldering ball 132 is located between two first soldering balls 122. In another embodiment, there is at least one second soldering ball in the gap among four of the first soldering balls. For example, in the lower right of FIG. 2A, within the central area surrounded by four first soldering balls 122, a second soldering ball 132 is placed. In some embodiments, some gaps between the first soldering balls 122 may not have a second soldering ball 132 placed therein. For example, in other areas of FIG. 2A, there are gaps between some first soldering balls 122 without a second soldering ball 132 therein.

In one embodiment, the first soldering balls 122 located near the edges of the interposer board 110 are subjected to a much higher stress than the first soldering balls 122 located at the center, and thus, the second soldering balls 132 are provided more in number between the first soldering balls 122 near the edges of the interposer board 110.

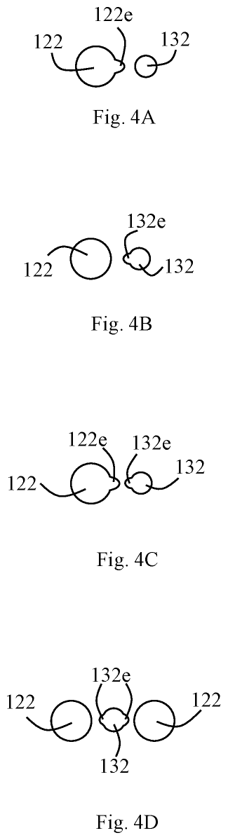

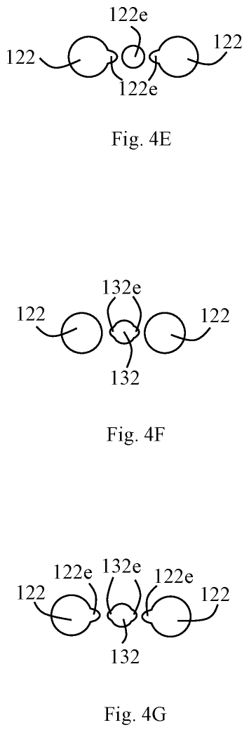

In the design of the first and second soldering balls 122 and 132, there are various options available, as referring to FIGS. 4A to 4G. In some embodiments, the first soldering ball 122 may include a first lateral jut 122e (FIGS. 4A, 4C, 4E, and 4G), formed on a first lateral side of the first soldering ball 122 facing the second soldering ball 132. Or, the second soldering balls 132 may include a second lateral jut 132e (FIGS. 4B, 4C, 4D, 4F, and 4G), formed on a second lateral side of the second soldering ball 132 facing the first soldering ball 122. In the reflow step, the first and second soldering balls 122 and 132 are melted and the adhesion between them is formed via the first lateral juts 122e and/or second lateral juts 132e.

In one embodiment, the heat dissipation effect of the second soldering balls 132 is lower than that of the first soldering balls 122. For example, the thermal conductivity coefficient of the second soldering balls 132 is lower than that of the first soldering balls 122, or the outer surface of the second soldering balls 132 is smaller than that of the first soldering balls 122. In this way, during the cooling process after the reflow step, the second soldering balls 132 located on both sides of the first soldering balls 122 can delay the temperature decrease of the first soldering balls 122, to prolong the solidification time of the first soldering balls 122, thus enhancing the adhesion effect between the first soldering balls 122 and the bottom side 110b.

If required, according to the present invention, a third ball grid array process may also be included, to further protect the first soldering balls 122 of the first ball grid array 120 and to increase the robustness and stability of the first soldering balls 122.

In one perspective, the present invention provides a method of fabricating semiconductor package structure, including: providing an interposer board 110, which includes a top side 110t and a bottom side 110b, wherein an integrated circuit IC is mounted on or above the top side 110t of the interposer board 110; performing a first ball grid array forming process, to form a first ball grid array 120 on the bottom side 110b of the interposer board 110, the first ball grid array 120 including plural first soldering balls 122; performing a second ball grid array forming process, to form a second ball grid array 130 on the bottom side 110b of the interposer board 110, the second ball grid array 130 including plural second soldering balls 132 respectively formed in gaps Gp between the first soldering balls 122 on the bottom sides 110b, wherein the first and second ball grid array forming processes are two different ball grid array forming processes; and performing a reflow step, wherein during the reflow step, at least a portion of the first soldering balls 122 are melted to be adhered to at least a portion of the second soldering balls 132; or, at least a portion of the second soldering balls 132 are melted to be adhered to at least a portion of the first soldering balls 122; or, at least a portion of the first soldering balls 122 and at least a portion of the second soldering balls 132 are melted to be adhered to one another. For details of each of these steps, please refer to the descriptions of the preceding embodiments, which are not redundantly repeated here.

According to the technology proposed by the present invention, the likelihood of cracks occurring in the first soldering balls is significantly reduced. As a result, the number of thermal cycle tests that the semiconductor packaging structure can withstand, or the product lifespan, is greatly extended.

The present invention has been described in considerable detail with reference to certain preferred embodiments thereof. It should be understood that the description is for illustrative purpose, not for limiting the scope of the present invention. An embodiment or a claim of the present invention does not need to achieve all the objectives or advantages of the present invention. The title and abstract are provided for assisting searches but not for limiting the scope of the present invention. Those skilled in this art can readily conceive variations and modifications within the spirit of the present invention. The spirit of the present invention is to arrange the second soldering balls of the second ball grid array within the gaps between the first soldering balls of the first ball grid array. Under the spirit of the present invention, two or more of the embodiments described hereinbefore can be used in combination. For example, two or more of the embodiments can be used together, or, a part of one embodiment can be used to replace a corresponding part of another embodiment. In view of the foregoing, the spirit of the present invention should cover all such and other modifications and variations, which should be interpreted to fall within the scope of the following claims and their equivalents.

What is claimed is:

1. A semiconductor package structure, including:
an interposer board, including a top side and a bottom side;
a first ball grid array located on the bottom side of the interposer board, the first ball grid array including a plurality of first soldering balls, wherein the first ball grid array provides a signal connection function between the interposer board and an external printed circuit board; and
a second ball grid array located on the bottom side of the interposer board, the second ball grid array including a plurality of second soldering balls, which are positioned within gaps between the first soldering balls on the bottom side.

2. The semiconductor package structure according to claim 1, further including an integrated circuit mounted on or above the top side of the interposer board.

3. The semiconductor package structure according to claim 1, wherein the first soldering balls are made of a conductive material, and the second soldering balls are made of a conductive material or a non-conductive material.

4. The semiconductor package structure according to claim 1, wherein in a reflow step, at least a portion of the first soldering balls are melted to be adhered to at least a portion of the second soldering balls; or, at least a portion of the second soldering balls are melted to be adhered to at least a portion of the first soldering balls.

5. The semiconductor package structure according to claim 4, wherein the second soldering balls are made of a conductive material, and the adhered second soldering balls and the first soldering balls form a redistribution circuit on the bottom side, wherein in the redistribution circuit, at least two of the first soldering balls are conducted to each other through the second soldering ball.

6. The semiconductor package structure according to claim 4, wherein the second soldering balls increase the solidified adhesion range on the bottom side after the first soldering balls are melted.

7. The semiconductor package structure according to claim 4, wherein in a reflow step, a portion of the second soldering balls are melted in the gaps between the first soldering balls, to form an adhesion structure, wherein the adhesion structure reduces an outward-exceeding height of the first soldering balls over the adhesion structure on the bottom side.

8. The semiconductor package structure according to claim 1, wherein the first and second soldering balls are respectively formed by two separate ball grid array forming processes.

9. The semiconductor package structure according to claim 1, wherein the first soldering balls and the second soldering balls are arranged on the bottom side in a non-stacked configuration.

10. The semiconductor package structure according to claim 9, wherein the first ball grid array and the second ball grid array are at the same layer level.

11. The semiconductor package structure according to claim 1, wherein there is at least one second soldering ball in the gap between two of the first soldering balls.

12. The semiconductor package structure according to claim 1, wherein there is at least one second soldering ball in the gap among four of the first soldering balls.

13. The semiconductor package structure according to claim 1, wherein at least one of the first soldering balls includes a first lateral jut at a first lateral side of the first soldering ball facing the second soldering ball; or, at least one of the second soldering balls includes a second lateral jut at a second lateral side of the second soldering ball facing the first soldering ball; wherein, in a reflow step, the first and second lateral juts form a melted adhesion between the first and second soldering balls.

14. A method of fabricating a semiconductor package structure, including:
providing an interposer board, which includes a top side and a bottom side, wherein an integrated circuit is disposed on or above the top side of the interposer board;
performing a first ball grid array forming process to form a first ball grid array on the bottom side of the interposer board, the first ball grid array including a plurality of first soldering balls;
performing a second ball grid array forming process to form a second ball grid array on the bottom side of the interposer board, the second ball grid array including a plurality of second soldering balls respectively disposed in gaps between the first soldering balls on the bottom sides;
performing a reflow step, wherein during the reflow step, at least a portion of the first soldering balls are melted to be adhered to at least a portion of the second soldering balls; or, at least a portion of the second soldering balls are melted to be adhered to at least a portion of the first soldering balls; or, at least a portion of the first soldering balls and at least a portion of the second soldering balls are melted to be adhered to one another.
